(19) United States
(12) Patent Application Publication
(10) Pub. No.: US 2008/0099918 A1
(43) Pub. Date: May 1, 2008

(54) SEMICONDUCTOR DEVICE INCLUDING A POROUS LOW-K MATERIAL LAYER STACK WITH REDUCED UV SENSITIVITY

(76) Inventors: Christof Streck, Coswig (DE); Volker Kahlert, Dresden (DE)

Correspondence Address: WILLIAMS, MORGAN & AMERSON, 10333 RICHMOND, SUITE 1100, HOUSTON, TX, 77042, US

(21) Appl. No.: 11/775,964

(22) Filed: Jul. 11, 2007

(30) Foreign Application Priority Data
Oct. 31, 2006 (DE) 10 2006 051 496.3

(51) Int. Cl. H01L 23/52; H01L 21/31

(52) U.S. Cl. 257/751; 438/762; 257/E23.141; 257/E21.24

(57) ABSTRACT

By forming a cap layer on a dielectric barrier layer of a low-k dielectric material stack, the interaction of UV radiation during the generation of pores in the low-k dielectric material may be significantly reduced. In some illustrative embodiments, the cap layer may comprise titanium oxide and/or vanadium oxide which may provide a high degree of reflectivity and absorption, respectively. The layer thickness of the cap layer may be 10 nm or significantly less, thereby reducing any adverse influence on the overall performance of the resulting layer stack.

### BACKGROUND OF THE INVENTION

1. Field of the Invention

Generally, the present disclosure relates to the fabrication of integrated circuits, and, more particularly, to the formation of metallization layers of reduced permittivity including porous low-k dielectric materials and advanced dielectric barrier layers.

2. Description of the Related Art

Semiconductor devices are typically formed on substantially disc-shaped substrates made of any appropriate material. The majority of semiconductor devices including highly complex electronic circuits are currently, and in the foreseeable future will be, manufactured on the basis of silicon, thereby rendering silicon substrates and silicon-containing substrates, such as silicon-on-insulator (SOI) substrates, viable carriers for forming semiconductor devices, such as microprocessors, SRAMs, ASICs (application specific ICs) and the like. The individual integrated circuits are arranged in an array form, wherein most of the manufacturing steps, which may involve several hundred individual process steps in sophisticated integrated circuits, are performed simultaneously for all chip areas on the substrate, except for photolithography processes, metrology processes and packaging of the individual devices after dicing the substrate. Thus, economic constraints drive semiconductor manufacturers to steadily increase the substrate dimensions, thereby also increasing the area available for producing actual semiconductor devices and thus increasing production yield. On the other hand, device dimensions are continuously reduced in view of performance criteria, as typically reduced transistor dimensions provide increased operating speed. Hence, during the manufacturing sequence, a large number of individual devices are passed through a plurality of process tools, wherein the transport and substrate handling processes may require well-defined mechanical characteristics in order to not unduly induce additional defects by material delamination and the like.

In modern integrated circuits, the circuit elements are formed in and on a semiconductor layer, while most of the electrical connections are established in one or more “wiring” layers, also referred to as metallization layers, wherein the electrical characteristics, such as resistivity, electromigration, etc., of the metallization layers significantly affect the overall performance of the integrated circuit. Due to the ongoing demand for shrinking the feature sizes of highly sophisticated semiconductor devices, copper, in combination with a low-k dielectric material, has become a frequently used alternative in the formation of so-called wiring structures comprising metallization layers having metal line layers and intermediate via layers. Metal lines act as intra-layer connections and vias act as inter-layer connections, which commonly connect individual circuit elements to provide the required functionality of the integrated circuit. Typically, a plurality of metal line layers and via layers stacked on top of each other are necessary to realize the connections between all internal circuit elements and I/O (input/output), power and ground pads of the circuit design under consideration.

For extremely scaled integrated circuits, the signal propagation delay is no longer limited by the circuit elements, for instance by field effect transistors, but is limited, owing to the increased density of circuit elements, which requires an even more increased number of electrical connections, by the close proximity of the metal lines, since the line-to-line capacitance increases as the spacing decreases. This fact, in combination with a reduced conductivity of the lines due to a reduced cross-sectional area, results in increased RC time constants. For this reason, traditional dielectrics, such as silicon dioxide (k>3.6) and silicon nitride (k>5), are increasingly replaced in metallization layers by dielectric materials having a lower permittivity, which are therefore also referred to as low-k dielectrics having a relative permittivity of approximately 3 or significantly less. The reduced permittivity of these dielectric materials is frequently further reduced by forming pores within the material. For this purpose, the materials have incorporated so-called porogens, i.e., typically organic compounds, which may be removed in a later stage, thereby leaving behind a highly porous structure in the dielectric base material. However, the density and mechanical stability or strength of the low-k materials may be significantly less compared to the well-approved dielectrics silicon dioxide and silicon nitride. As a consequence, the electrical behavior of the metallization layers, although being superior in view of device performance, may be inferior with respect to reliability and also with respect to substrate handling and transport, as explained above, compared to devices having a conventional metallization layer. Therefore, the metallization level may represent a delicate structure, in which diverging requirements with respect to electrical performance and reliability and stability have to be precisely balanced.

With reference to FIG. 1, a typical conventional semiconductor device and a process for manufacturing the same is described, which includes a metallization layer on the basis of a porous low-k material.

In FIG. 1, a semiconductor device 100 comprises a substrate 101 which may include any circuit elements, such as transistor elements, capacitors and the like. For convenience, these circuit elements are not shown. Formed on the substrate 101, which may represent a bulk silicon substrate or an SOI substrate, is a dielectric layer 102, which may be comprised, at least partially, of a low-k material or any other dielectric material, depending on the device requirements. A metal region 103 is formed within the dielectric layer 102 and may represent any highly conductive device area, such as a contact area of a circuit element or a metal region of a lower metallization layer. The metal region 103 may be separated from the material of the dielectric layer 102 by a barrier layer 104, which is typically provided as a layer for reducing the diffusivity of metal atoms into the dielectric layer 102 and to also reduce the diffusion of atoms from the dielectric layer 102 into the metal region 103. Moreover, the barrier layer 104 may also enhance the adhesion of the metal with respect to the dielectric material. In sophisticated devices, the metal region 103 may comprise copper and the barrier layer 104 may be comprised of one or more layers including tantalum, tantalum nitride, titanium, titanium nitride and the like. Formed above the dielectric layer 102 and the metal region 103 is a dielectric barrier layer 105 comprised of a dielectric material that substantially prevents diffusion of metal atoms of the metal region 103 into overlying regions. Furthermore, the barrier layer 105 may act as an etch stop layer during the patterning of low-k dielectric material to be formed above the layer 105. The dielectric barrier layer 105 may comprise silicon nitride, which may efficiently reduce copper diffusion. However, in view of a desired overall low permittivity, the material of the barrier layer 105 may also be selected to exhibit a moderately low dielectric constant, which may be accomplished on the basis of silicon carbide, nitrogen-enriched silicon carbide, which exhibits a high diffusion blocking effect and may also act as an etch stop layer during subsequent patterning processes. Respective low-k barrier layers may also be referred to as “blok” (barrier low-k) layers.

The device further comprises a low-k dielectric layer 106, which may be comprised of any appropriate material, such as a mixture of silicon, oxygen and hydrogen, polymer materials and the like. The low-k dielectric layer 106 may have incorporated therein pore generating species, that is, a porogen 107, which may be removed, at least partially, on the basis of a treatment 108. The selection of an appropriate candidate for a porogen material may depend on the characteristics of the treatment 108. For example, for a thermal treatment, a reduced number of porogen materials is currently available, thereby also restricting the compatibility with subsequent process steps. In other regimes, the treatment is therefore designed as an irradiation with UV (ultra violet) light, which may provide a wide class of porogens.

A typical process flow for forming the semiconductor device 100 may comprise the following processes. After having completed any circuit elements in the substrate 101, the dielectric layer 102 and the metal region 103 with the conductive barrier layer 104 may be formed by a well-established process sequence. Then, the dielectric barrier layer 105 may be deposited by plasma enhanced chemical vapor deposition (PECVD) on the basis of well-established process recipes so as to form, for instance, a nitrogen-enriched silicon carbide layer. Thereafter, the dielectric layer 106 is deposited, for instance, by PECVD, spin-on techniques and the like. For example, the low-k dielectric layer 106 may be formed, for instance, by depositing SiCOH from trimethylsilane (3MS) or 4MS and the like, wherein an oxygen treatment may be performed prior to the actual deposition process in order to appropriately prepare the exposed surface of the barrier layer 105. During this treatment and/or the deposition of the low-k material, a certain degree of surface modification of the barrier layer 105 up to several nanometers may result, thereby also changing the characteristics of the barrier layer 105 to a certain degree, while the remaining portion of the layer 105 may provide the desired characteristics. As previously explained, the mechanical stability of a low-k layer stack may have a significant influence on the further processes in terms of substrate handling and also in terms of performance of the finalized device. For example, the barrier layer 105 may be applied with compressive stress for enhancing the overall mechanical stability of the low-k dielectric stack, which may be particularly important for porous dielectric materials.

After the deposition of the low-k dielectric layer 106 including the porogen material 107, for instance, by CVD, the treatment 108 is performed in order to reduce the sacrificial material 107, which is frequently provided as an organic material, and to generate voids on the basis of the porogen material 107, wherein, due to increased process flexibility, preferably a UV treatment is used, possibly in combination with an assisting heat treatment. Thereafter, the further processing may be continued by forming a cap layer on the layer 106, if required, and by patterning the layer 106 so as to receive trenches and via openings that may be filled with metal in a subsequent stage. It turns out, however, that the characteristics of the resulting layer stack and in particular of the barrier layer 105 may result in reduced performance and/or stability when the treatment 108 includes UV irradiation. Hence, although advantageous in view of process flexibility, a UV based treatment for generating pores in a low-k dielectric material may be associated with significant changes of the resulting layer stack.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to a techniques for forming a sophisticated low-k dielectric layer stack wherein the low-k dielectric material may be subjected to a radiation treatment to increase the porosity of the low-k dielectric material. Contrary to conventional approaches, in which a high degree of flexibility in selecting respective porogen materials is desired, the influence of the corresponding radiation treatment on the underlying dielectric barrier layer may be significantly reduced by providing a respective radiation blocking cap layer which may significantly reduce the penetration of the dielectric barrier material by incident radiation. Consequently, significant changes in material characteristics, such as a reduction of compressive stress which may advantageously be generated in the dielectric barrier layer for enhancing mechanical stability and enhancing electromigration performance of the entire layer stack, may be substantially maintained. Furthermore, by providing highly reflective and/or absorbing materials on the dielectric barrier layer, the corresponding layer thickness may be selected moderately thin, thereby also reducing any adverse effect of the corresponding cap layer with respect to the overall permittivity of the low-k dielectric layer stack.

According to one illustrative embodiment disclosed herein, a method comprises forming a dielectric barrier layer above a dielectric layer having formed therein a metal region wherein the dielectric layer is located above a substrate of a semiconductor device. Furthermore, a cap layer is formed on the dielectric barrier layer wherein the cap layer is configured to substantially block UV radiation. The method further comprises forming a low-k dielectric layer above the cap layer and performing a treatment using UV radiation for modifying the low-k dielectric layer.

According to another illustrative embodiment disclosed herein, a method comprises forming a dielectric barrier layer above a substrate of a semiconductor device and forming a metal-containing UV protection layer on the dielectric layer. Furthermore, a low-k dielectric material is formed above the UV protection layer and finally the low-k dielectric material is treated with UV radiation.

According to yet another illustrative embodiment disclosed herein, a semiconductor device comprises a dielectric barrier layer formed above a substrate, and a metal-containing cap layer is formed on the dielectric barrier layer. Furthermore, a porous low-k dielectric layer is formed on the metal-containing cap layer and a metal line is formed in the porous low-k dielectric layer.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a conventional semiconductor device during a manufacturing sequence for forming a porous low-k dielectric layer above a dielectric barrier layer on the basis of a UV treatment, thereby significantly changing the material characteristics of the dielectric barrier layer;

FIGS. 2a-2d schematically illustrates cross-sectional views of a semiconductor device during various manufacturing stages in forming a low-k dielectric layer for sophisticated semiconductor devices, wherein a cap layer may be formed on top of a dielectric barrier layer in order to reduce penetration of radiation into the dielectric barrier layer according to illustrative embodiments; and

FIG. 2e schematically illustrates a cross-sectional view of the semiconductor device according to other illustrative embodiments in which different materials may be commonly provided to increase the UV blocking characteristics.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein addresses the problem of material modifications of a dielectric barrier layer of advanced metallization structures in sophisticated semiconductor devices, wherein the corresponding dielectric barrier layer is one important component in the complex dielectric structure that provides the required diffusion blocking characteristics, as well as mechanical stability and the electromigration performance of the resulting metallization structure. As previously explained, the mechanical stability of sophisticated metallization structures based on low-k dielectric materials, the permittivity of which may even further be reduced by generating a certain degree of porosity, is highly critical during the processing of the devices and also after finalizing the devices during operation, for instance, with respect to the electromigration behavior. Consequently, the change of material characteristics may therefore significantly affect the subsequent process steps, as previously explained, as well as the finally obtained performance of the device. For example, a moderate degree of compressive stress provided within a low-k dielectric layer stack may result in an increased mechanical stability and thus enhance electrical performance so that, in sophisticated applications, the corresponding dielectric barrier layer may be provided with high compressive stress. Consequently, any reduction of the compressive stress or even a conversion into tensile stress, as may be caused by UV radiation during the generation of pores in a low-k dielectric material, may therefore reduce reliability and electromigration performance of the resulting metallization structure. On the other hand, an efficient mechanism, i.e., a wide class of porogen materials, is highly desirable in order to provide efficient techniques for further reducing the relative permittivity of low-k dielectric materials. Consequently, the subject matter disclosed herein provides a technique for significantly reducing the interaction of UV radiation with the dielectric barrier layer while at the same time not unduly affecting the overall characteristics of the dielectric layer stack, for instance, with respect to relative permittivity. For this purpose, an efficient protection layer or cap layer may be provided above the dielectric barrier layer, which may comprise a high degree of reflectivity and/or absorbing capability even at a moderately thin layer thickness, wherein, in some illustrative embodiments, the corresponding material of the cap layer or protection layer may include a metal component in order to provide the desired characteristics.

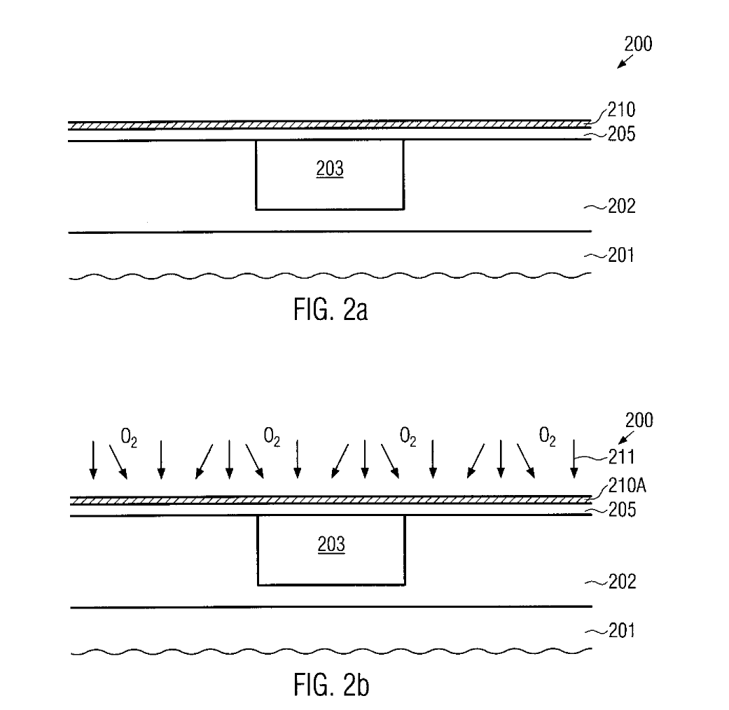

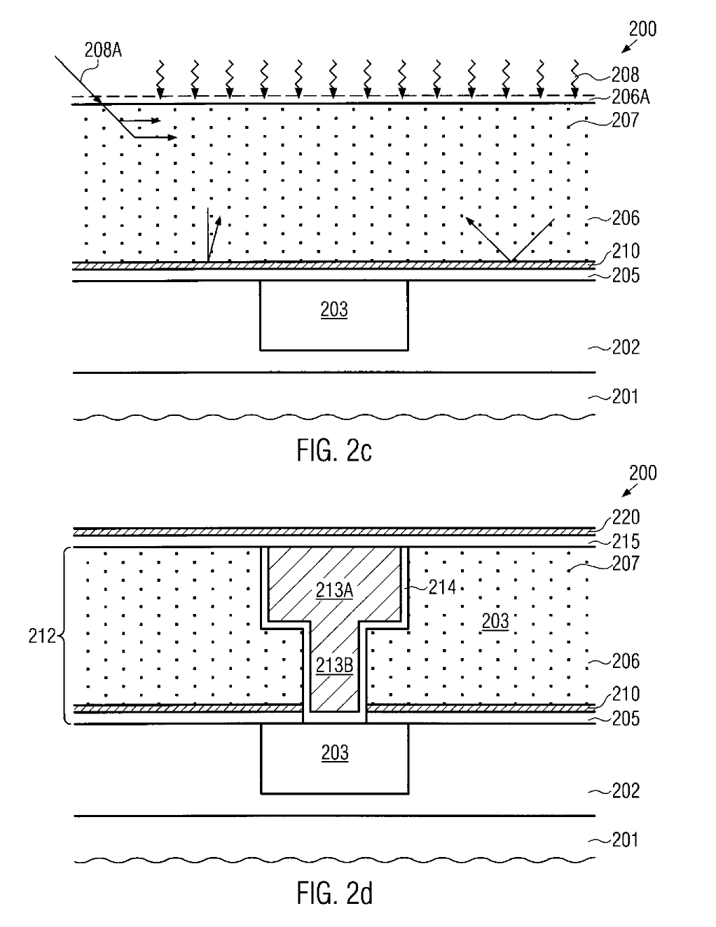

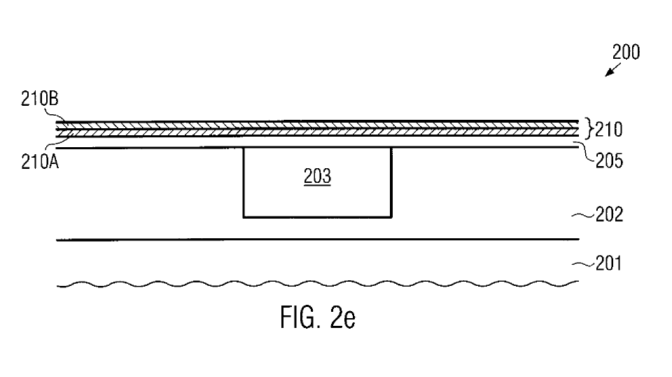

FIG. 2a schematically illustrates a cross-sectional view of a semiconductor device 200 at a manufacturing stage in which a low-k dielectric material for a sophisticated metallization structure is to be formed. In this manufacturing stage, the semiconductor 200 may comprise a substrate 201, which may represent any appropriate carrier material for forming therein and thereon respective circuit elements (not shown), such as transistors, capacitors and the like. It should be appreciated that the substrate 201 may include, in the case of highly advanced semiconductor devices, circuit elements such as field effect transistors having critical dimensions of 50 nm and even less when, for instance, the gate length of sophisticated logic integrated circuits is considered. In some illustrative embodiments, the substrate 201 may represent a silicon-based carrier material having formed therein crystalline silicon-based active regions in which P-channel transistors and N-channel transistors are to be formed having a gate length of 100 nm and significantly less, such as 50 nm and less. For convenience, any such circuit elements are not shown in the drawings. Furthermore, the semiconductor device 200 may comprise a dielectric material 202, which may represent a conventional dielectric material, such as silicon dioxide, silicon nitride and the like, depending on the device requirements. In other cases, the dielectric layer 202 may comprise a low-k dielectric material when the layer 202 may represent one of a plurality of metallization levels of the device 200. In this respect, a dielectric material is referred to as a low-k dielectric material when a relative permittivity thereof is approximately 3.0 or less, wherein it should be appreciated that the corresponding relative permittivity may significantly depend on the homogeneity of the material since the corresponding dielectric behavior may be adjusted by providing respective voids or pores in a specific material layer.

Moreover, the semiconductor device 200 may comprise a conductive material region 203 which may represent, in some illustrative embodiments, a metal line or any other metal region including a highly conductive metal, such as copper and the like. In other cases, the region 203 may represent a contact portion of a circuit element and the like. Furthermore, appropriate conductive barrier materials may be provided, if required. For instance, if the region 203 represents a copper-containing metal region, respective conductive barriers as are established in the art may be provided as is also discussed with reference to the metal region 103 of the device 100. Furthermore, the semiconductor device 200 may comprise a dielectric barrier layer 205 which may also provide, in illustrative embodiments, a high etch selectivity with respect to a low-k dielectric material to be formed above the dielectric barrier layer 205. Furthermore, the dielectric barrier layer 205 may have a respective material characteristic so as to reliably confine the conductive material of the region 203. That is, the barrier layer 205 may substantially suppress any diffusion of metal into the dielectric materials and may also reduce diffusion of unwanted species, such as oxygen, fluorine and the like, into the region 203. In some illustrative embodiments, the dielectric barrier layer 205 may be provided in the form of a blok layer having a significantly reduced relative permittivity, for instance, compared to a silicon nitride material. For instance, nitrogen-containing silicon carbide may be used, since it may exhibit a significant etch selectivity with respect to a plurality of anisotropic etch chemistries used for the patterning of a low-k dielectric material still to be formed above the layer 205. In some illustrative embodiments, the material characteristics of the layer 205 may be selected with respect to increased diffusion blocking characteristics as well as with respect to other material properties, such as a high degree of compressive stress, while the corresponding etch selectivity may be provided or at least enhanced by a cap layer 210 formed on the dielectric barrier layer 205. The cap layer 210 may be comprised of any appropriate material having a high capability of reflecting and/or absorbing radiation of a specified wavelength range and, in particular, ultraviolet (UV) radiation. It should be appreciated that, in the present case, UV radiation is to be considered as electromagnetic radiation including a wavelength range from approximately 400 nm up to approximately 100 nm. Consequently, the cap layer 210 may be considered as a UV protection layer or blocking layer since UV radiation according to the above identified wave length range may be efficiently hindered in penetrating the dielectric barrier layer 205. In this respect, substantially blocking UV radiation is to be understood as reducing UV radiation penetrating the barrier layer 205 by approximately 50% or more relative to the intensity of the incoming radiation incident on the cap layer 210.

In some illustrative embodiments, the material characteristics of the cap layer 210 are selected such that approximately 80% or more of the incoming UV radiation is blocked, that is, reflected and/or absorbed, depending on the characteristics of the layer 210. In some illustrative embodiments, the cap layer 210 may comprise a metal, which, in one illustrative embodiment, may comprise titanium and/or vanadium, wherein the corresponding metals may be converted into an oxide, thereby providing the insulting characteristic of the layer 210. In one illustrative embodiment, the cap layer 210 may be comprised of titanium oxide, which may provide a high degree of reflectivity even for radiation in the above-specified UV wavelength range. In a further embodiment, the cap layer 210 may be comprised of vanadium oxide (V₂O₅) which may have a high extinction coefficient, thereby providing a high degree of absorbing capability. In other illustrative embodiments, the cap layer 210 may be comprised of two or more metal components and/or sub-layers as will be described later on in more detail with reference to FIG. 2e.

The semiconductor device 200 as shown in FIG. 2a may be formed on the basis of the following processes. After forming any circuit elements in and above the substrate 201, the dielectric layer 202 may be formed on the basis of well-established techniques. For example, if the dielectric layer 202, in combination with the region 203, may represent a metallization layer of the device 200, respective process sequences may be used as will be described later on when forming a respective low-k dielectric layer above the dielectric barrier layer 205. Similarly, the conductive region 203 may be formed on the basis of any well-established process techniques which may include a patterning sequence for forming a respective trench or other opening in the dielectric material 202, depositing an appropriate barrier material if highly conductive metals such as copper are contained in the region 203, followed by an appropriate deposition technique. After planarizing the respective surface topography, the barrier layer 205 may be formed in order to reliably confine the conductive material in the region 203 which may be accomplished on the basis of well-established techniques. For instance, PECVD recipes may be used for depositing an appropriate material, such as nitrogen-containing silicon carbide, wherein respective process parameters may be adjusted so as to obtain a high degree of compressive stress of the layer 205. For instance, a reduced degree of ion bombardment during the deposition process may provide an increased compressive stress of the layer 205 as deposited.

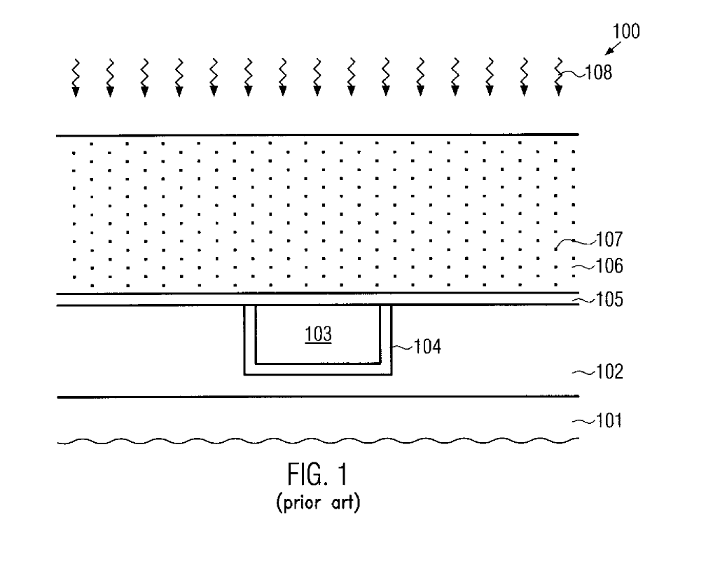

Next, the cap layer 210 may be formed on the basis of appropriate deposition techniques which, in some illustrative embodiments, may include chemical vapor deposition (CVD) like processes on the basis of appropriate precursor materials. For instance, titanium oxide may be deposited by CVD on the basis of well-established recipes while, in some illustrative embodiments, even a self-limiting deposition process may be used, in which the deposition may be performed in separate steps, wherein each deposition step provides a specified layer thickness. Consequently, enhanced process control may be obtained in order to precisely adjust the thickness of the cap layer 210. For example, in some illustrative embodiments, the cap layer 210 may have a thickness of approximately 10 nm and less, or 5 nm and less, thereby reducing the influence on the overall characteristics of the low-k dielectric layer stack still to be formed. For example, in conventional techniques, the low-k dielectric material may be deposited on the dielectric barrier layer 205 as is, for instance, explained with reference to FIG. 1, wherein typically a significant surface modification may also result up to a thickness of approximately 5 nm so that the overall integration behavior may not substantially change when providing the cap layer 210 having a thickness in the above-specified range.

FIG. 2b schematically illustrates the semiconductor device 200 in accordance with yet other embodiments. In this manufacturing stage, the dielectric barrier layer 205 may have been formed as previously explained and an intermediate layer 210A may be formed on the barrier layer 205. The intermediate layer 210A may have appropriate material characteristics which may be appropriately changed by a treatment 211 so as to obtain the desired optical behavior with respect to the above-identified UV wavelength range. In one illustrative embodiment, the intermediate layer 210A may be deposited as a metal layer or a metal-containing layer on the basis of well-established techniques, such as sputter deposition and the like. For instance, in view of efficient tool utilization in a semiconductor process line, the layer 210A may be provided in the form of a titanium or a titanium nitride layer, which may be formed on the basis of well-established process recipes, since titanium or titanium nitride may also be used as an efficient conductive barrier layer in other process strategies. For example, in the contact level, i.e., the level for providing respective contact plugs to circuit elements, titanium/titanium nitride may frequently be used as an efficient barrier layer. Hence, respective process recipes and process tools may readily be available and may be used for depositing the intermediate layer 210A thereby not unduly reducing overall process throughput. In other illustrative embodiments, the intermediate layer 210A may be provided in the form of a vanadium layer which may also be formed on the basis of sputter deposition techniques. In still other illustrative embodiments, the intermediate layer 210A may be obtained on the basis of a surface treatment of the barrier layer 205, for instance by a plasma treatment, a low-energy implantation process and the like, wherein an appropriate species may be incorporated into the surface portion of the layer 205. For instance, by incorporating an appropriate metal species such as vanadium and the like on the basis of a plasma treatment, the corresponding optical characteristics, for instance, with respect to the extinction coefficient of the barrier layer 205, may be appropriately adjusted in order to obtain a high degree of absorbing capability with respect to the above-identified wavelength range.

After forming the intermediate layer 210A, which in some illustrative embodiments may include the deposition of an appropriate metal-containing layer, such as a titanium layer, a titanium nitride layer, a vanadium layer and the like, the treatment 211 may be performed to convert the intermediate layer 210A into an insulating layer which may, for instance, be accomplished on the basis of an oxidation process. Consequently, the intermediate layer 210A may be converted into the cap layer 210, for instance, comprised of titanium oxide, vanadium oxide and the like. In one illustrative embodiment, the treatment 211 may be performed as an oxygen treatment as may be performed prior to the deposition of a silicon, oxygen and hydrogen-containing low-k dielectric material, thereby obtaining a highly efficient process flow, wherein conventional process techniques may be used when titanium is used as the metal in the intermediate layer 210A.

FIG. 2c schematically illustrates the semiconductor device 200 during a further advanced manufacturing stage. In this phase, the device 200 may comprise a low-k dielectric material 206 which may be subjected to a UV radiation treatment 208 in order to generate a desired degree of porosity on the basis of a respective porogen material 207. As previously explained, using the treatment 208 on the basis of UV radiation provides a high degree of flexibility in choosing appropriate pore generating materials 207 which may also result in increased flexibility in selecting an appropriate material composition for the low-k dielectric material 206. Consequently, any appropriate material, such as a polymer material, a silicon-based material and the like, may be used for the layer 206 and may be deposited on the basis of any appropriate deposition technique, wherein the corresponding porogen material 207 may be incorporated according to device requirements. During the radiation treatment 208, a chemical reaction between the material 207 caused by the radiation may result in the generation of material inhomogeneities in the form of respective voids or pores, which may therefore correspondingly reduce the overall permittivity of the material 206. During the treatment 208, a significant amount of radiation may also be incident on the cap layer 210 which may, however, contrary to conventional approaches, significantly reduce the intensity of radiation penetrating the barrier layer 205 so that the material characteristic thereof may be substantially maintained. For example, if a high degree of compressive stress has been generated during deposition of the layer 205, a corresponding compressive stress may be substantially maintained, thereby contributing to enhanced mechanical stability and superior electromigration performance of the conductive region 203. The blocking characteristics of the layer 210 may be obtained on the basis of increasing the reflectivity compared to the barrier layer 205. For instance, a titanium oxide material may result in an increased reflectivity, which may also contribute to an increased efficiency of the treatment 208 due to the continuous back reflection of radiation into the material 206. In other illustrative embodiments, the cap layer 210 may exhibit a high degree of absorbing capability, thereby also reducing the amount of radiation finally reaching the dielectric barrier layer 205. In still other illustrative embodiments, a corresponding high degree of absorption may be combined with a high surface reflectivity as will be explained later on in more detail.

In some illustrative embodiments, the treatment 208 may be performed on the basis of a substantially parallel radiation 208A, which may be coupled into the material 206 so as to propagate approximately parallel (or at least in a substantially non-vertical direction) with respect to the layer 210, thereby further reducing the probability for radiation penetrating the barrier layer 205. In this case, the respective thickness of the layer 210 may even further be reduced in order to lessen the overall influence on the finally obtained performance of the layer stack comprised of the layers 206, 210 and 205. For example, a corresponding layer 206A may be provided on top of the low-k dielectric material 206 which may have a greater index of refraction compared to the material of the layer 206, in order to deflect the beam 208A in the desired manner. For example, the layer 206A may represent a cover layer for increasing the mechanical stability of the material 206 or the layer 206A may be provided in the form of a sacrificial layer which may be removed after the treatment 208. In this case, the beam 208A may be directed to the device 200 under a specified angle so that a corresponding deflection may occur upon entering the material 206 in order to obtain an approximately parallel propagation. Although the homogeneity of the material 206 may be reduced during the treatment 208, which may result in an increasing degree of scattered light, the overall intensity of radiation incident on the layer 210 may be reduced and the corresponding angles of incidence with respect to the layer 210 may be significantly increased, thereby increasing the optical thickness “seen” by the corresponding incident beam 208A. This may result in an increased efficiency for a given thickness of the layer 210, or the initial thickness of the layer 210 may further be reduced. In other illustrative embodiments, the material characteristics of the cap layer 210 may have to meet less strict constraints with respect to reflectivity and/or absorption due to the significantly reduced overall intensity caused by the increased average angle of incidence. Hence, appropriate dielectric materials may be used for the layer 210, for instance, by appropriately adjusting the optical characteristics thereof which may be accomplished on the basis of well-established techniques. For instance, during the deposition of the barrier layer 205, an upper portion thereof may be treated so as to have an increased extinction coefficient or an appropriate index of refraction. In this case, an even enhanced compatibility with conventional process techniques and materials may be achieved, thereby further reducing an influence of the layer 210 on the finally obtained overall characteristics of the layer stack defined by the materials 206, 210 and 205.

FIG. 2d schematically illustrates the semiconductor device 200 in a further advanced manufacturing stage. In this stage, the device 200 may comprise a dielectric layer stack 212 which may represent the dielectric material of a metallization layer wherein a significant amount of low-k dielectric material in the form of a porous material may be provided. For instance, the low-k dielectric material 206 may represent the dominant portion of the layer stack 212 which may further include the cap layer 210 and the dielectric barrier layer 205. In the illustrative embodiment shown, a corresponding interconnect structure, which may comprise a metal line 213A in combination with a respective via 213B, may be substantially embedded into the low-k dielectric material 206 while in other illustrative embodiments (not shown) the line 213A may be embedded into the material 206 while the remaining portion of the layer stack 212 may be formed from a different material. The dielectric material 206 may comprise respective pores or voids in order to correspondingly exhibit a low permittivity, which may be 2.5 or even less in sophisticated applications. If the corresponding metals in the metal line 213A and the via 213B may exhibit an increased diffusivity in the low-k dielectric material 206, a corresponding barrier material 214 may be provided. Furthermore, in some illustrative embodiments, the metallization layer comprised of the layer stack 212 and the metal line 213A and the via 213B may receive a further dielectric barrier layer 215 which may have substantially the same characteristics as the layer 205. A further low-k dielectric material may be formed above the dielectric barrier layer 215 and a further cap layer 220 may be provided which may have substantially the same characteristics as the layer 210 in order to significantly reduce the interaction of radiation with the material of the barrier layer 215 in a later manufacturing stage, for instance, for generating a high degree of porosity as is also explained with reference to the material 206.

A typical process flow for forming the semiconductor device 200 as shown in FIG. 2d may comprise the following processes. After the treatment 208 for forming a desired degree of porosity in the material 206 with significantly reduced influence on the barrier layer 205 due to the cap layer 210, an appropriate patterning regime may be applied for forming the metal line 213A and the via 213B. For instance, appropriate photolithography processes in combination with anisotropic etch recipes may be used in order to form respective openings in the material 206. In this patterning process, a corresponding via opening may be formed first and subsequently a corresponding trench or inversely the trench opening may be formed first and thereafter a corresponding via opening may be formed. In still other cases, the material of the layer 206 may be provided with an appropriate thickness so as to accommodate the via 213B only. Thereafter, a further material layer may be formed in which the corresponding metal line 213A may be provided. Irrespective of the respective process sequence used, the corresponding etch process for forming the via opening for the via 213B may be reliably controlled on the basis of the layers 210 and/or 205. For example, the barrier layer 205 may have a pronounced etch selectivity with respect to the material 206, for instance, when well-established barrier materials, such as nitrogen-enriched silicon carbide, silicon carbide and the like may be used. In other illustrative embodiments, the characteristics of the cap layer 210 may additionally provide a certain degree of etch selectivity, thereby enabling the selection of material characteristics of the material layer 205 with respect to the barrier and adhesion behavior to provide enhanced electromigration performance while the stopping capabilities in the corresponding etch process are less critical. Furthermore, any species contained in the cap layer 210, even though released only in a very minute amount during the corresponding etch process, may nevertheless provide a distinct endpoint detection signal, thereby also enhancing the degree of controllability of the corresponding etch process. Thereafter, the corresponding openings may be filled with an appropriate material, such as the barrier material 214, and a highly conductive metal, such as copper, copper alloys and the like. Next, the corresponding metal of the metal line 213A may be reliably confined by forming the barrier layer 215, followed by the cap layer 220, if a further layer of low-k dielectric material is to be formed above the barrier layer 215.

Consequently, by providing the barrier layer 205 with desired material characteristics, for instance, comprising a high compressive stress, the overall mechanical and electrical performance of the semiconductor device 200 during processing and during operation may be adjusted to a desired high performance level, wherein subsequent processes, such as a UV radiation treatment used for generating a desired degree of porosity in the low-k material, may have a significantly reduced influence.

FIG. 2e schematically illustrates the semiconductor device 200 according to a further illustrative embodiment in which the cap layer 210 may comprise two or more materials, for instance in the form of sub-layers indicated as 210A and 210B which may provide the desired UV blocking characteristics. In one illustrative embodiment, the layer 210A may have a high degree of absorbance, which may be obtained by providing a respective material, such as vanadium oxide, while the sub-layer 210B may provide enhanced surface reflectivity, which may be accomplished by forming a titanium oxide layer. Hence, upon exposure by UV radiation, a significant amount of radiation may be reflected by the layer 210B while radiation propagating into the layer 210A may be efficiently absorbed therein. In other illustrative embodiments, the layer 210B may have a moderately high absorbing capability for the wavelength range under consideration while additionally the layer 210A may provide a high degree of reflectivity. In other illustrative embodiments, the layer 210A may represent a dielectric material, which may be formed with a high degree of compatibility with respect to the layer 205, while the layer 210B may represent a very thin layer of approximately 5 nm and significantly less, which may be formed on the basis of an appropriate metal component such as titanium in order to provide a high degree of reflectivity, whereas the layer 210A may provide increased absorption, for instance, relative to the material 205, thereby additionally blocking a certain amount of radiation that may pass through the reflective layer 210B. Similarly, the layer 210B may be provided with a high degree of absorbing capability, for instance, in the form of a vanadium oxide layer. In this case, a thickness thereof may be selected in the range of 5 nm and less, while the layer 210A may act as an additional “buffer” layer in order to further suppress any undue interaction of the UV radiation with the material of the layer 205. Consequently, by providing two or more sub-layers, the respective material characteristics and the respective manufacturing processes for forming the cap layer 210 may be tailored to provide a high degree of flexibility and/or compatibility with preceding and subsequent process steps. Furthermore, by appropriately combining the sub-layers 210A and 210B, the overall thickness, and thus influence on the overall performance, of the stack may be reduced. For example, an appropriate surface modification of the barrier material 205 may result in moderately efficient UV blocking characteristics of the layer 210A while nevertheless providing a high process compatibility with the process for forming the layer 205 while the deposition of an ultra-thin metal-containing layer in the form of the layer 210B may provide an even more enhanced performance of the cap layer 210.

As a result, the subject matter disclosed herein provides a semiconductor device and a method for forming the same in which the degree of porosity of a low-k dielectric material may be adjusted on the basis of a UV treatment in combination with respective porogen materials, wherein the interaction of the UV radiation with a dielectric barrier material used for reliably confining high conductive metals, such as copper and the like, may be significantly reduced compared to conventional approaches. For this purpose, an efficient cap layer may be formed having a thickness in the range of 10 nm and significantly less, which may provide UV radiation blocking capabilities in order to reduce the fraction of UV radiation actually penetrating the barrier layer material. Consequently, the material characteristics of this layer may be substantially maintained, for instance, a high degree of compressive stress may be maintained even after the UV treatment, thereby providing the possibility of forming metallization structures including low-k dielectric materials with a high degree of porosity while nevertheless providing increased mechanical stability and electromigration performance. The cap layer, which may comprise two or more sub-layers, may in some illustrative embodiments be provided in the form of a metal-containing layer, thereby providing superior reflectivity and/or absorbing capabilities. For instance, titanium, vanadium and the like may be efficiently used to form a respective metal oxide on the basis of highly controllable deposition processes such as atomic layer deposition (ALD), CVD like processes, or wherein a corresponding metal compound may be deposited on the basis of physical vapor deposition, which may then be converted into a highly insulating material in a subsequent treatment such as an oxidation process. Thus, even well-established process techniques and respective process tools may be used, thereby not unduly contributing to additional process complexity compared to conventional approaches. The efficiency of the corresponding cap layer may even further be enhanced by modifying the corresponding radiation treatment such that the radiation has parallel component to increase the angle of incidence, thereby even further reducing the amount of radiation that may interact with the material provided below the cap layer.

Consequently, the subject matter disclosed herein may be applied in the context of highly sophisticated semiconductor devices requiring metallization structures with low-k dielectric material having a highly porous structure, wherein nevertheless respective dielectric barrier layers, such as blok layers, may maintain the desired material characteristics, such as high degree of compressive stress and the like.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a dielectric barrier layer above a dielectric layer having formed therein a conductive region, said dielectric layer located above a substrate of a semiconductor device;
forming a cap layer above said dielectric barrier layer, said cap layer configured to substantially block UV radiation;
forming a low-k dielectric layer above said cap layer; and
performing a treatment using UV radiation for modifying a permittivity of said low-k dielectric layer.

2. The method of claim 1, wherein forming said cap layer comprises depositing a metal-containing material.

3. The method of claim 2, further comprising converting said metal-containing material into a dielectric material by initiating a chemical reaction.

4. The method of claim 3, wherein said chemical reaction comprises an oxidation process.

5. The method of claim 1, wherein said cap layer is formed by at least one of a self-limiting deposition process and a chemical vapor deposition process.

6. The method of claim 1, wherein said cap layer is formed by a physical vapor deposition process.

7. The method of claim 1, wherein said dielectric barrier layer is formed with an intrinsic compressive stress.

8. The method of claim 1, wherein said cap layer is formed as a reflective layer for said UV radiation.

9. The method of claim 1, wherein said cap layer is formed as an absorption layer for said UV radiation.

10. The method of claim 1, wherein forming said cap layer comprises forming a titanium oxide containing layer.

11. The method of claim 1, wherein forming said cap layer comprises forming a vanadium oxide containing layer.

12. The method of claim 1, wherein forming said cap layer comprises forming a first sub-layer on said dielectric barrier layer and a second sub-layer on said first sub-layer.

13. A method, comprising:
forming a dielectric barrier layer above a substrate of a semiconductor device;
forming a metal-containing UV protection layer on said dielectric barrier layer;
forming a low-k dielectric material above said UV protection layer; and
treating said low-k dielectric material with UV radiation to increase a porosity of said low-k dielectric material.

14. The method of claim 13, wherein forming said UV protection layer comprises depositing a metal layer and treating the metal layer to form a non-conductive material.

15. The method of claim 13, further comprising performing an oxygen treatment prior to forming said low-k dielectric layer, wherein said oxygen treatment results in a non-conductive material of said UV protection layer.

16. A semiconductor device, comprising:
a dielectric barrier layer formed above a substrate;
a metal-containing cap layer formed on said dielectric barrier layer;
a porous low-k dielectric layer formed on said metal-containing cap layer; and
a conductive line formed in said porous low-k dielectric layer.

17. The semiconductor device of claim 16, wherein said cap layer comprises at least one of titanium and vanadium.

18. The semiconductor device of claim 16, wherein said cap layer has a thickness of approximately 10 nm or less.

19. The semiconductor device of claim 18, wherein said dielectric barrier layer comprises silicon and carbon.

20. The semiconductor device of claim 19, wherein said dielectric barrier layer is a nitrogen containing silicon carbide layer.
